(19) United States
(12) Patent Application Publication
(10) Pub. No.: US 2026/0047002 A1
(43) Pub. Date: Feb. 12, 2026

(54) WIRING BOARD AND METHOD OF MANUFACTURING THE SAME

(71) Applicant: AOI ELECTRONICS CO., LTD., Takamatsu-shi (JP)

(72) Inventors: Takaaki KATO, Kagawa (JP); Naoki TAKATA, Kagawa (JP)

(21) Appl. No.: 19/272,243

(22) Filed: Jul. 17, 2025

(30) Foreign Application Priority Data
Aug. 9, 2024 (JP) 2024134611

(51) Int. Cl. H05K 1/02; H05K 1/03; H05K 3/02

(52) U.S. Cl. CPC H05K 1/0296; H05K 1/0306; H05K 3/02

(57) ABSTRACT

A wiring board includes a ceramic substrate having an upper surface and a lower surface and a conductor pattern formed on the upper surface of the ceramic substrate. The conductor pattern includes a base metal layer formed on the upper surface of the ceramic substrate and a metal layer formed on the upper surface of the ceramic substrate so as to entirely cover the base metal layer. The base metal layer contains at least one of titanium and chromium in addition to copper and silver. The metal layer contains copper as a main component, and a weight percentage of silver contained in the metal layer is smaller than a weight percentage of silver contained in the base metal layer. Side surfaces of the base metal layer are covered with the metal layer.

### CROSS REFERENCES TO RELATED APPLICATIONS

The present application claims priority to Japanese Patent Application No. 2024-134611 filed on Aug. 9, 2024, the disclosure of which is incorporated herein by reference.

### TECHNICAL FIELD

The present invention relates to a wiring board and a method of manufacturing the same.

### BACKGROUND

As a technique of forming a wiring pattern on a ceramic substrate, there is a technique of interposing a base layer under a metal layer made of copper. For example, Japanese Unexamined Patent Application Publication No. 2009-253196 (Patent Document 1) describes a method of forming a wiring pattern by applying a high-melting-point metal paste onto a sintered aluminum nitride substrate, firing it, stacking a copper paste on a wiring pattern made of the high-melting-point metal, and then firing it.

### SUMMARY

When forming a conductor pattern on a ceramic substrate, it is necessary to improve the adhesiveness between the ceramic substrate and the conductor pattern. When the conductor pattern containing copper as a main component contains a silver component, the adhesiveness between the ceramic substrate and the conductor pattern can be improved. However, when the conductor pattern contains a silver component, the migration of silver occurs in some cases. From the viewpoint of improving the reliability of the wiring board, it is necessary to prevent the migration due to silver.

A wiring board according to one embodiment includes a ceramic substrate having a first surface and a second surface on an opposite side of the first surface and a first conductor pattern formed on the first surface of the ceramic substrate. The first conductor pattern includes a first base metal layer formed on the first surface of the ceramic substrate and a first metal layer formed on the first surface of the ceramic substrate so as to entirely cover the first base metal layer. The first base metal layer contains at least one of titanium and chromium in addition to copper and silver. The first metal layer contains copper as a main component and a weight percentage of silver contained in the first metal layer is smaller than a weight percentage of the silver contained in the first base metal layer. Side surfaces of the first base metal layer are covered with the first metal layer.

A method of manufacturing a wiring board according to another embodiment includes: (a) preparing a ceramic substrate having a first surface and a second surface on an opposite side of the first surface; (b) applying a first base metal paste onto the first surface of the ceramic substrate; (c) forming a first base metal layer by firing the first base metal paste; (d) after the (c), applying a first metal paste so as to entirely cover the first base metal layer; and (e) after the (d), forming a first metal layer by firing the first metal paste. The first base metal paste contains at least one of titanium particles and chromium particles in addition to copper particles and silver particles. A weight percentage of copper particles contained in the first metal paste is larger than a weight percentage of the copper particles contained in the first base metal paste, and a weight percentage of silver particles contained in the first metal paste is smaller than a weight percentage of the silver particles contained in the first base metal paste. In the (d), side surfaces of the first base metal layer are covered with the first metal paste.

According to the above embodiment, it is possible to improve the performance of the wiring board.

### BRIEF DESCRIPTION OF DRAWINGS

FIG. 1 is a top view of a wiring board of one embodiment.

FIG. 2 is an enlarged cross-sectional view taken along the line A-A in FIG. 1.

FIG. 3 is an enlarged cross-sectional view taken along the line B-B in FIG. 1.

FIG. 4 is an enlarged cross-sectional view of a wiring board in a studied example relative to FIG. 2.

FIG. 5 is an enlarged transparent plan view illustrating a planar positional relationship between the base metal layer and the metal layer covering the base metal layer illustrated in FIG. 2 and FIG. 3.

FIG. 6 is an enlarged cross-sectional view illustrating a detailed structure example of each layer constituting the conductor pattern illustrated in FIG. 2.

FIG. 7 is an enlarged transparent plan view of a wiring board in a modification relative to FIG. 5.

FIG. 8 is an enlarged cross-sectional view taken along the line C-C in FIG. 7.

FIG. 9 is an enlarged cross-sectional view taken along the line D-D in FIG. 7.

FIG. 10 is an enlarged cross-sectional view illustrating a detailed structure example of each layer constituting the conductor pattern illustrated in FIG. 8.

FIG. 11 is a bottom view of a wiring board in a modification relative to the wiring board illustrated in FIG. 1.

FIG. 12 is a cross-sectional view taken along the line E-E in FIG. 11.

FIG. 13 is an explanatory diagram illustrating an example of a manufacturing process of the wiring board of one embodiment.

FIG. 14 is an enlarged cross-sectional view illustrating the first base metal paste applying step illustrated in FIG. 13.

FIG. 15 is an enlarged cross-sectional view illustrating the second base metal paste applying step illustrated in FIG. 13.

FIG. 16 is an enlarged cross-sectional view illustrating a state in which a base layer is formed by the base layer firing step illustrated in FIG. 13.

FIG. 17 is an enlarged cross-sectional view illustrating the first metal paste applying step illustrated in FIG. 13.

FIG. 18 is an enlarged cross-sectional view illustrating a state in which a metal layer is formed by the first metal layer firing step illustrated in FIG. 13.

FIG. 19 is an explanatory diagram illustrating an example of a manufacturing process of a wiring board in a modification relative to FIG. 13.

FIG. 20 is an enlarged cross-sectional view illustrating the second metal paste applying step illustrated in FIG. 19.

FIG. 21 is an enlarged view illustrating the second metal layer firing step illustrated in FIG. 19.

FIG. 22 is an enlarged cross-sectional view illustrating the second base metal paste applying step in a modification relative to FIG. 15.

FIG. 23 is an enlarged cross-sectional view of a conductor pattern obtained in the modification illustrated in FIG. 22.

### DETAILED DESCRIPTION OF THE INVENTION

### Explanation of Description Form, Basic Terminology, and Usage in this Application

In this application, the embodiment will be described in a plurality of sections or the like when required as a matter of convenience. However, these sections or the like are not irrelevant to each other and serve as each part of a single example unless otherwise stated, and a part of one example relates to the other example as details or a part or the entire of a modification regardless of the order of description. Also, the repetitive description of similar parts will be omitted in principle. Further, the constituent elements in the embodiment are not always indispensable unless otherwise stated or except for the case where the constituent elements are theoretically limited to that number or the constituent elements are obviously indispensable from the context.

In each drawing for the embodiment, the same or similar parts are denoted by the same or similar reference characters or reference numbers, and the descriptions thereof are not repeated in principle.

In the following description, a wiring board refers to, for example, a member in which a conductor pattern is formed on a base such as a ceramic substrate made of ceramics. The conductor pattern includes a terminal pattern for ensuring electrical connection to external devices such as electronic components and semiconductor components in addition to a wiring pattern extending in a linear shape (strip shape). Furthermore, the conductor pattern sometimes includes large-area conductor patterns such as a bonding pad for mounting external devices, a ground plane, and a power plane.

In the following description, a term “main component” is sometimes used when describing a metal element constituting a metal layer. For example, as to a “metal layer containing copper as a main component”, the metal material constituting the metal layer contains at least 90% by weight or more of copper, preferably 99% by weight or more of copper.

Also, the description is sometimes given using a term “weight proportion” when describing a metal element constituting a metal layer. The “weight proportion of an element” is a value obtained by dividing a weight value of a target element contained per unit volume by the total weight value per unit volume. For example, a “weight proportion of silver in a member A” is a value obtained by dividing a weight value of silver contained in a part (or all) of the member A by a weight value of the part (or all) of the member A. Also, a “weight proportion of silver particles in a member A” is a value obtained by diving a weight value of silver particles contained in a part (or all) of the member A by a weight value of the part (or all) of the member A.

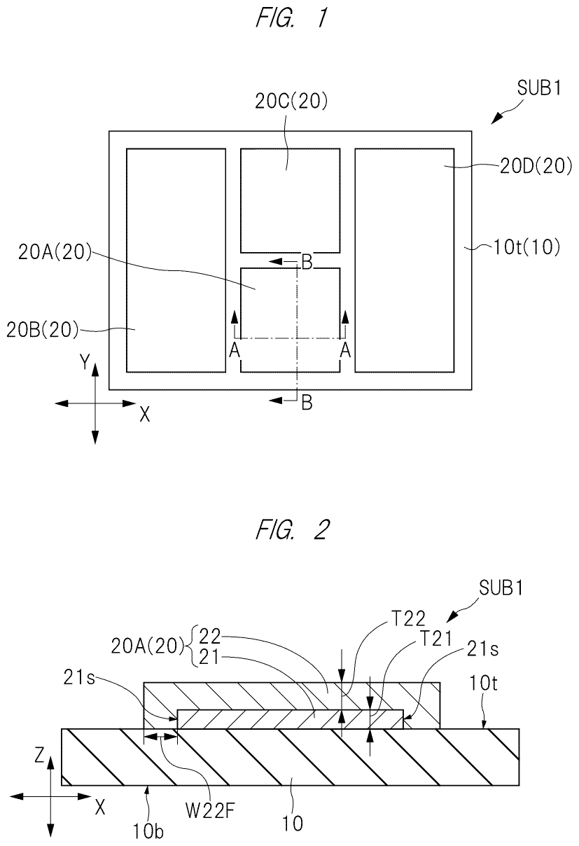

Also, in the following description, directions such as an X direction, a Y direction, and a Z direction are sometimes used. For example, in FIG. 1 to be described later, the X direction and the Y direction are illustrated. The X direction and the Y direction intersect with each other. In the example described below, the X direction is orthogonal to the Y direction. In the following, an X-Y plane including the X direction and the Y direction is described as a surface parallel to a main surface of a wiring board.

Also, a surface (for example, a surface parallel to an X-Z plane including the X direction and the Z direction and a surface parallel to a Y-Z plane including the Y direction and the Z direction) intersecting with the X-Y plane is referred to as a side surface. In the following description, “in plan view” refers to a case of seeing the surface parallel to the X-Y plane except for the case where it is clearly specified that it should be particularly interpreted as a different meaning. Also, the normal direction relative to the X-Y plane is described as the “Z direction” or the thickness direction. The “thickness” and “height” refer to the length in the “Z direction” except for the case where it is clearly specified that it should be particularly interpreted as a different meaning. The X direction, the Y direction, and the Z direction are directions that intersect with each other, and more specifically, are directions that are orthogonal to each other.

### Wiring Board

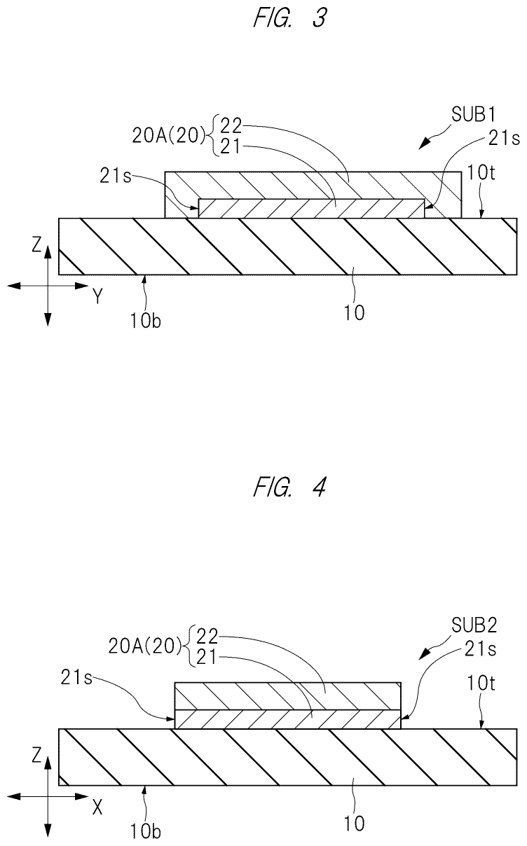

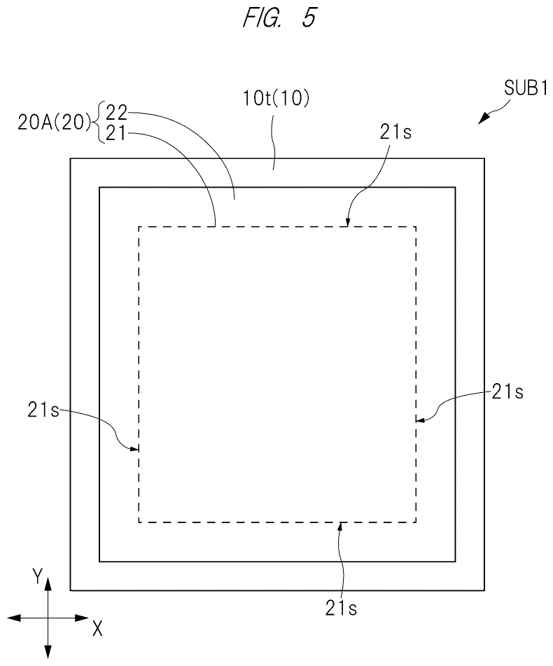

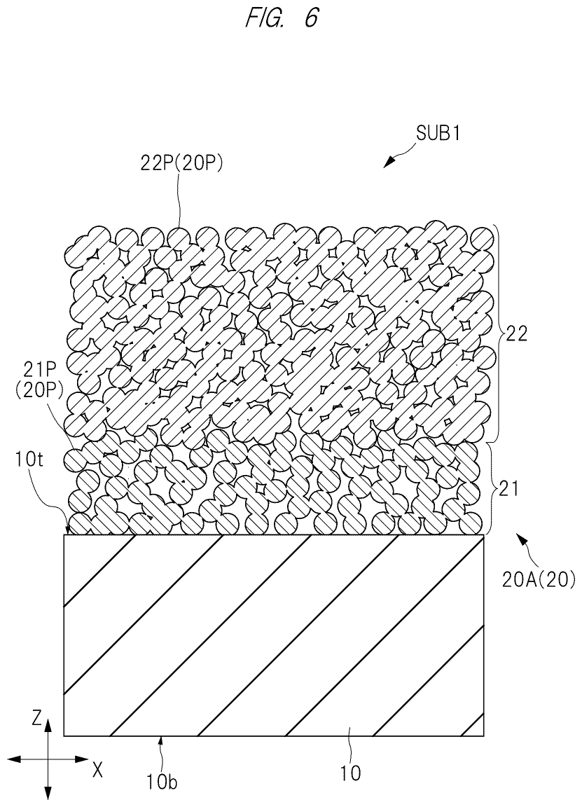

FIG. 1 is a top view of a wiring board of this embodiment. FIG. 2 is an enlarged cross-sectional view taken along the line A-A in FIG. 1. FIG. 3 is an enlarged cross-sectional view taken along the line B-B in FIG. 1. FIG. 4 is an enlarged cross-sectional view of a wiring board in a studied example relative to FIG. 2. FIG. 5 is an enlarged transparent plan view illustrating a planar positional relationship between the base metal layer and the metal layer covering the base metal layer illustrated in FIG. 2 and FIG. 3. In FIG. 5, an outline of a base metal layer 21 illustrated in FIG. 2 and FIG. 3 is indicated by a dotted line.

As illustrated in FIG. 2, a wiring board SUB1 of this embodiment includes a ceramic substrate 10 having an upper surface (surface) 10t and a lower surface (surface) 10b on an opposite side of the upper surface 10t and a conductor pattern 20A formed on the upper surface 10t of the ceramic substrate 10.

In the example illustrated in FIG. 1, a conductor pattern 20B, a conductor pattern 20C, and a conductor pattern 20D which are arranged apart from the conductor pattern 20A are formed on the upper surface 10t of the ceramic substrate 10 in addition to the conductor pattern 20A. The conductor patterns 20A to 20D are electrically separated from each other.

The plurality of conductor patterns 20 include those different in planar area and planar shape. Each of the plurality of conductor patterns 20 has the same layer structure. In the following, a detailed structure of the conductor pattern 20A illustrated in FIG. 2 will be described as a representative example of the conductor pattern 20.

The ceramic substrate 10 is made of, for example, silicon nitride or aluminum nitride. The conductor pattern 20 is a metal layer containing copper as a main material. The wiring board SUB1 in which the conductor pattern 20 made of a metal layer containing copper as a main material is bonded on the ceramic substrate 10 is used as, for example, a wiring board for a power module incorporated in a power supply circuit.

From the viewpoint of electrical conduction characteristics or heat dissipation characteristics, it is preferable to use a metal layer containing copper as a main material for the conductor pattern 20A. However, since copper does not have a very high adhesiveness to the ceramic substrate 10, measures to improve the bonding strength between the ceramic substrate 10 and the conductor pattern 20A are required.

Therefore, in the case of this embodiment, as illustrated in FIG. 2 and FIG. 3, the base metal layer 21 is interposed between the metal layer 22 and the upper surface 10t of the ceramic substrate 10. The base metal layer 21 contains at least one of titanium and chromium in addition to copper and silver. The base metal layer 21 functions as a bonding layer for improving the bonding strength between the metal layer 22 mainly made of copper and the ceramic substrate 10.

As will be described in detail later, each of the base metal layer 21 and the metal layer 22 illustrated in FIG. 2 and FIG. 3 is a porous metal layer in which a plurality of metal particles are bonded to each other. The size of the voids in the metal layer can be adjusted by the average particle size of the plurality of metal particles and the degree of sintering (firing temperature and firing time).

Incidentally, from the viewpoint of simply improving the bonding strength between the copper layer and the ceramic substrate 10, a structure in which the metal layer 22 is stacked on the base metal layer 21 and side surfaces 21s of the base metal layer 21 are not covered with the metal layer 22 as illustrated in FIG. 4 as a wiring board SUB2 in a studied example suffices.

However, the study by the inventors of this application has revealed that there is a problem caused by electromigration of silver contained in the base metal layer 21 in the case of the structure of the wiring board SUB2. For example, the weight percentage of silver contained in the base metal layer 21 is larger than the weight percentage of copper contained in the base metal layer 21. By increasing the weight percentage of silver contained in the base metal layer 21, the bonding strength between the base metal layer 21 and the ceramic substrate 10 can be improved.

However, when electromigration occurs in the silver contained in the base metal layer 21, the silver component contained in the base metal layer 21 spreads around the conductor pattern 20A along the upper surface 10t of the ceramic substrate 10. In this case, the electrical characteristics of the current flowing through the conductor pattern 20A are unstable.

Alternatively, when the conductor pattern 20A and the conductor pattern 20B are adjacent to each other as illustrated in FIG. 1, there is a fear that the conductor pattern 20A and the conductor pattern 20B may be short-circuited via the diffused silver component depending on the degree of diffusion of electromigration.

Thus, the inventors of this application have studied a method for improving the bonding strength between the metal layer 22 and the ceramic substrate 10 while suppressing the electromigration of silver component, and have found the structure of this embodiment.

Namely, as illustrated in FIG. 2 and FIG. 3, the conductor pattern 20A includes the base metal layer 21 formed on the upper surface 10t of the ceramic substrate 10 and the metal layer 22 formed on the upper surface 10t of the ceramic substrate 10 so as to entirely cover the base metal layer 21. The base metal layer 21 contains at least one of titanium and chromium in addition to copper and silver. The metal layer 22 contains copper as a main component, and the weight percentage of silver contained in the metal layer 22 is smaller than the weight percentage of silver contained in the base metal layer 21. It is particularly preferable that the metal layer 22 does not contain silver. The side surfaces 21s of the base metal layer 21 are covered with the metal layer 22.

Specifically, as illustrated in FIG. 5, the base metal layer 21 forms a quadrangle in plan view and has four side surfaces 21s. As illustrated in FIG. 2 and FIG. 3, the four side surfaces 21s of the base metal layer 21 are all covered with the metal layer 22.

In addition, the expression “the weight percentage of silver contained in the metal layer 22 is smaller than the weight percentage of silver contained in the base metal layer 21” also includes the case where the metal layer 22 does not contain silver. In addition, the “weight percentage of silver” means the weight percentage of silver contained per unit volume. In the case of this embodiment, the weight percentage of silver in the metal layer 22 is at least 10% by weight or less, preferably 5% by weight or less, and particularly preferably 1% by weight or less. The lower the weight percentage of silver contained in the metal layer, the more preferable it is, and it is particularly preferable that the metal layer 22 does not contain silver as described above.

When the side surfaces 21s of the base metal layer 21 are covered with the metal layer 22 whose weight percentage of silver is small in this way, electromigration of silver does not progress. Therefore, in the case of the wiring board SUB1, the electrical reliability is higher than that of the wiring board SUB2 illustrated in FIG. 4.

On the other hand, the base metal layer 21 contains silver and titanium or silver and chromium, so that the bonding strength with the ceramic substrate 10 is improved. Therefore, the weight percentage of silver contained in the base metal layer 21 is as high as about 20 to 30% by weight. Also, the weight percentage of titanium or chromium contained in the base metal layer 21 is, for example, about 1 to 5% by weight.

Therefore, the weight percentage of copper contained in the base metal layer 21 is lower than the weight percentage of copper contained in the metal layer 22. For example, the weight percentage of copper contained in the base metal layer 21 is, for example, about 30 to 50% by weight. On the other hand, the weight percentage of copper contained in the metal layer 22 is 90% by weight or more.

In the example of this embodiment, as illustrated in FIG. 5, the area of a contact surface between the base metal layer 21 and the ceramic substrate 10 is larger than the area of a contact surface between the metal layer 22 and the ceramic substrate 10. Since the base metal layer 21 is a layer for increasing the bonding strength between the ceramic substrate 10 and the conductor pattern 20A as described above, the bonding strength is increased in proportion to the area of the contact surface between the base metal layer 21 and the ceramic substrate 10.

On the other hand, if there is a certain extent of the area of the contact surface between the metal layer 22 and the ceramic substrate 10, electromigration can be prevented from occurring on the side surface 21s of the base metal layer 21. Therefore, in a range in which the area of the contact surface between the metal layer 22 and the ceramic substrate 10 is larger than a certain value, the effect of suppressing electromigration is almost constant. For example, in FIG. 2, a width W22F of the part of the metal layer 22 that is in direct contact with the ceramic substrate 10 is about 30 μm to 50 μm. If the width W22F is 30 μm or more, electromigration can be suppressed.

Therefore, from the viewpoint of increasing the bonding strength between the conductor pattern 20A and the ceramic substrate 10 and suppressing electromigration, it is preferable that the area of the contact surface between the base metal layer 21 and the ceramic substrate 10 is larger than the area of the contact surface between the metal layer 22 and the ceramic substrate 10 as illustrated in FIG. 5.

Next, the detailed structure of each layer illustrated in FIG. 2 and FIG. 3 will be described. FIG. 6 is an enlarged cross-sectional view illustrating a detailed structure example of each layer constituting the conductor pattern illustrated in FIG. 2.

As illustrated in FIG. 6, each of the base metal layer 21 and the metal layer 22 is a porous metal layer in which a plurality of metal particles 20P are bonded to each other. The density of a plurality of metal particles 22P in the metal layer 22 is higher than the density of a plurality of metal particles 21P in the base metal layer 21. The “density of a plurality of metal particles” is a value obtained by dividing the total of the weight of the plurality of metal particles per unit volume by the unit volume. Therefore, the density of the plurality of metal particles decreases as the volume of the gaps contained in the metal layer increases.

For this reason, the expression “the density of a plurality of metal particles 22P in the metal layer 22 is higher than the density of a plurality of metal particles 21P in the base metal layer 21” above can be rephrased as “the average value of the volume of the gaps present per unit volume of the base metal layer 21 is larger than the average value of the volume of the gaps present per unit volume of the metal layer 22.” Such a state can be determined as follows based on an image taken by a microscope such as a scanning electron microscope (SEM).

That is, when a predetermined number of arbitrary cross sections (cross sections obtained by cutting the conductor pattern 20 in the thickness direction) of the conductor pattern 20 (for example, at about 3 to 10 positions) are photographed, the average value of the area of the gaps per unit area of the base metal layer 21 is larger than the average value of the area of the gaps per unit area of the metal layer 22. In this case, it is estimated that the average value of the volume of the gaps present per unit volume of the base metal layer 21 is larger than the average value of the volume of the gaps present per unit volume of the metal layer 22.

Moreover, the plurality of metal particles 21P constituting the base metal layer 21 contain copper particles and silver particles. Also, the plurality of metal particles 21P contain at least one of titanium particles and chromium particles.

Meanwhile, the majority (for example, 90% by weight or more) of the plurality of metal particles 22P constituting the metal layer 22 is made up of copper particles. In the example illustrated in FIG. 6, the plurality of metal particles 22P are all copper particles. As a modification relative to this embodiment, the plurality of metal particles 22P may contain metal particles other than copper particles. For example, for the purpose of improving the characteristics of the metal layer 22, metal particles made of a metal other than copper are contained in the plurality of metal particles 22P constituting the metal layer 22 in some cases. However, as described above, from the viewpoint of suppressing electromigration, it is preferable that the weight percentage of silver particles contained in the plurality of metal particles 22P is a small value including zero.

The weight percentage of copper contained in the metal layer 22 and the base metal layer 21 can also be expressed as follows. That is, the weight percentage of copper contained in the metal layer 22 is larger than the weight percentage of copper contained in the base metal layer 21.

In other words, the metal layer 22 contains more copper than the base metal layer 21. Therefore, the electrical characteristics of the metal layer 22 are higher than the electrical characteristics of the base metal layer 21. Further, the thermal conductivity of the metal layer 22 is higher than the thermal conductivity of the base metal layer 21. Namely, the metal layer 22 transmits heat more easily than the base metal layer 21.

Also, as illustrated in FIG. 2, in the region overlapping with the base metal layer 21, a thickness T22 of the metal layer 22 is larger than a thickness T21 of the base metal layer 21. In other words, the thickness T21 of the base metal layer 21 is smaller than the thickness T22 of the metal layer 22. In this case, since the electrical characteristics of the conductor pattern 20A are determined mainly by the electrical characteristics of the metal layer 22, it is possible to suppress the degradation of the electrical characteristics due to the use of the base metal layer 21.

For example, the thickness T21 of the base metal layer 21 is about 10 μm to 20 μm. On the other hand, the thickness T22 of the metal layer 22 is about 100 μm to 300 μm. As will be described in detail later, the upper limit of the thickness T22 is set to 300 μm due to restrictions in the manufacturing process. If a method described later as a modification is used in the method of manufacturing the wiring board, the value of the thickness T22 can exceed 300 μm to be, for example, about 1 mm.

Alternatively, the following can be said from the viewpoint of thermal conduction characteristics. That is, by reducing the thickness T21 of the base metal layer 21 whose thermal conductivity is lower than that of the metal layer 22, the distance between the metal layer 22 and the ceramic substrate 10 is shortened in the part where the metal layer 22 and the base metal layer 21 are stacked. In other words, the section occupied by the base metal layer 21 can be shortened in the thermal conduction path from the metal layer 22 to the ceramic substrate 10, so that the thermal conduction characteristics of the entire conductor pattern 20A can be improved.

In addition, as described with reference to FIG. 1, the wiring board SUB1 has the plurality of conductor patterns 20 spaced apart from one another. In FIG. 1 to FIG. 3, FIG. 5, and FIG. 6, the structure of the conductor pattern 20A has been described as a representative example, but the conductor patterns 20B, 20C, and 20D illustrated in FIG. 1 each have a structure similar to that of the conductor pattern 20A. Therefore, for example, the wiring board SUB1 illustrated in FIG. 1 can be expressed as follows.

That is, the wiring board SUB1 further has the conductor pattern 20B formed on the upper surface 10t of the ceramic substrate 10 so as to be spaced apart from the conductor pattern 20A. The conductor pattern 20A and the conductor pattern 20B are adjacent to each other in plan view. The conductor pattern 20B includes the base metal layer 21 and the metal layer 22 like the conductor pattern 20A illustrated in FIG. 1 to FIG. 3, FIG. 5, and FIG. 6.

In addition, the wiring board SUB1 has the plurality of conductor patterns 20 spaced apart from each other on the upper surface 10t of the ceramic substrate 10. Each of the plurality of conductor patterns 20 includes the base metal layer 21 and the metal layer 22 like the conductor pattern 20A illustrated in FIG. 2 to FIG. 6.

If the above-mentioned electromigration occurs in the structure in which the plurality of conductor patterns 20 spaced apart from one another in plan view are arranged in this manner, there is a fear that the conductor patterns 20 adjacent to each other may be short-circuited depending on the degree of diffusion of silver component.

In the case of this embodiment, like the conductor pattern 20A described with reference to FIG. 2, FIG. 3, and FIG. 5, the side surfaces 21s of the base metal layer 21 of each of the plurality of conductor patterns 20 are covered with the metal layer 22 whose weight percentage of silver is small, so that electromigration of the silver component contained in the base metal layer 21 can be suppressed. Therefore, it is possible to prevent the short circuit between the adjacent conductor patterns 20.

### Modification of Structure of Conductor Pattern

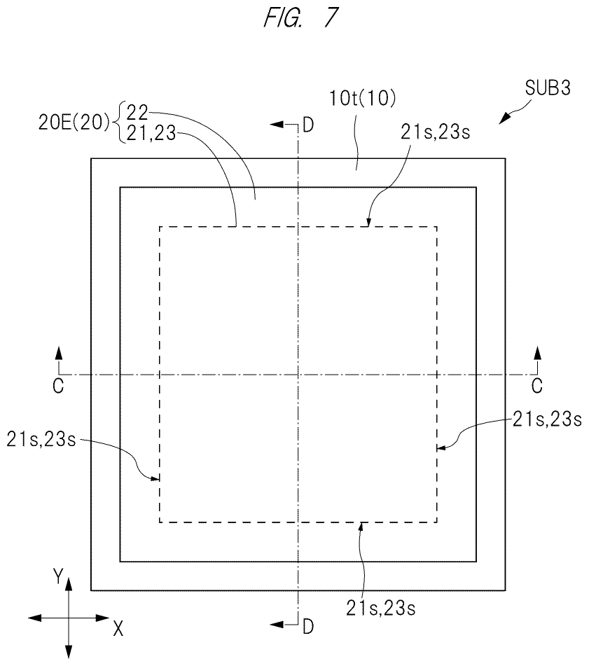

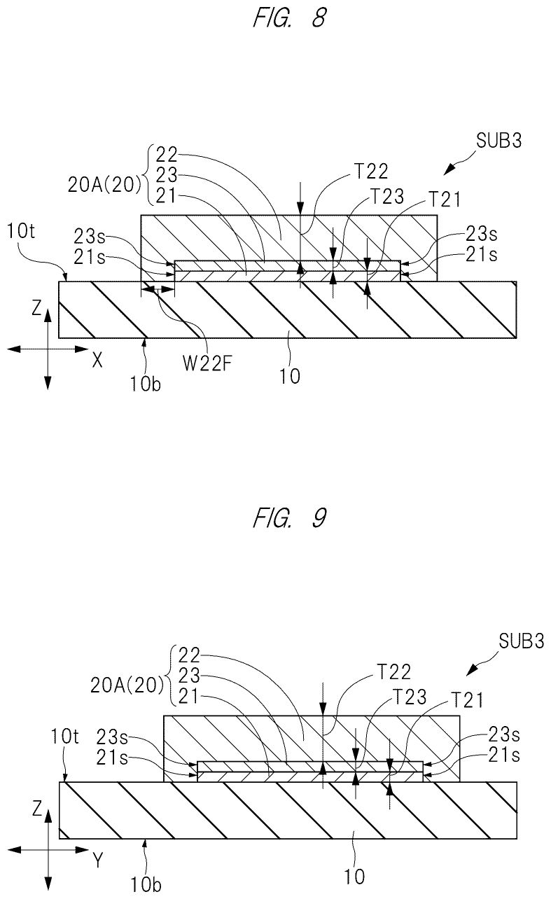

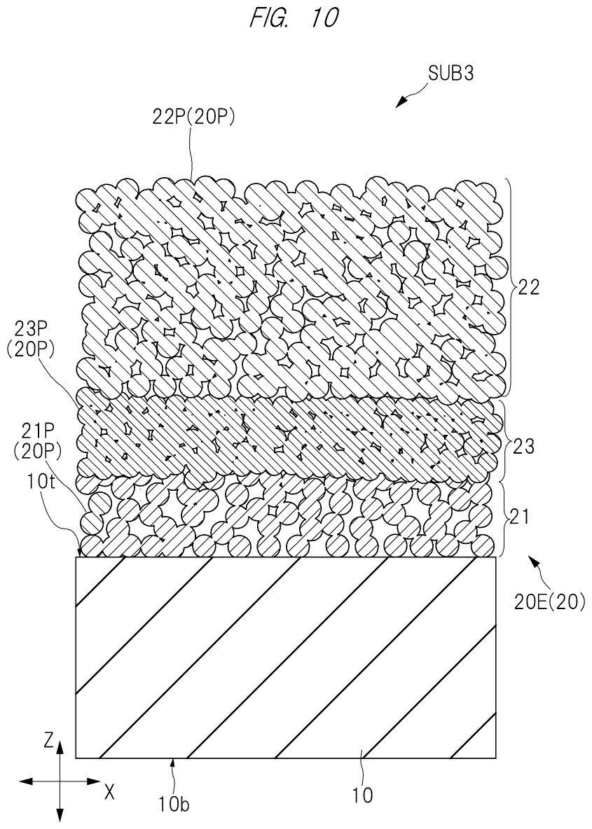

Next a modification of the conductor pattern 20A illustrated in FIG. 2 will be described. FIG. 7 is an enlarged transparent plan view of a wiring board in a modification relative to FIG. 5. FIG. 8 is an enlarged cross-sectional view taken along the line C-C in FIG. 7. FIG. 9 is an enlarged cross-sectional view taken along the line D-D in FIG. 7. FIG. 10 is an enlarged cross-sectional view illustrating a detailed structure example of each layer constituting the conductor pattern illustrated in FIG. 8.

Note that a conductor pattern 20E illustrated in FIG. 7 to FIG. 10 can be applied in place of one or more of the plurality of conductor patterns 20 illustrated in FIG. 1. Therefore, a wiring board SUB3 illustrated in FIG. 7 to FIG. 10 has the plurality of conductor patterns 20 formed on the upper surface 10t like the wiring board SUB1 illustrated in FIG. 1. Also, each of the plurality of conductor patterns 20 has a structure similar to that of a conductor pattern 20E described below.

The wiring board SUB3 illustrated in FIG. 7 to FIG. 10 is different from the wiring board SUB1 illustrated in FIG. 1 to FIG. 3, FIG. 5, and FIG. 6 in the following points.

First, the conductor pattern 20E of the wiring board SUB3 further includes a base metal layer 23 formed on the base metal layer 21 in addition to the base metal layer 21 and the metal layer 22 described above. Each of the base metal layer 21 and the base metal layer 23 is entirely covered with the metal layer 22, including the side surfaces 21s of the base metal layer 21 and side surfaces 23s of the base metal layer 23.

The wiring board SUB1 has the structure provided with the base metal layer 21 in a single layer. However, the base metal layer may be a stacked film made up of a plurality of layers as in the wiring board SUB3 other than a single layer. In the case where the base metal layer is a stacked film made up of a plurality of layers, the base metal layer 21 has the four side surfaces 21s and the base metal layer 23 has the four side surfaces 23s when each of the base metal layer 21 and the base metal layer 23 forms a quadrangle in plan view as illustrated in FIG. 7. In this case, even if the base metal layer 23 contains silver, it is possible to prevent the electromigration due to the silver contained in the base metal layer 23.

In the case of this modification, the base metal layer 23 contains copper as a main component. More specifically, 90% by weight or more of the metal element constituting the base metal layer 23 is copper element. Also, the weight percentage of silver contained in the base metal layer 23 is smaller than the weight percentage of silver contained in the base metal layer 21. For example, the weight percentage of silver per unit volume of the base metal layer 23 is 1% by weight or less.

As will be described in detail later, in the manufacturing process of the wiring board, when the metal layer 22 is stacked in a state in which a metal film such as silver, titanium, or chromium is formed on the upper surface of the base metal layer, it is difficult to bond the metal film other than copper formed on the upper surface of the base metal layer and the metal layer 22 in some cases.

In the case of this modification, the base metal layer 23 whose copper purity is higher than that of the base metal layer 21 is interposed between the base metal layer 21 and the metal layer 22, which makes the bonding state between the metal layer 22 and the base metal layer 23 good. Furthermore, by forming the base metal layer 21 and the base metal layer 23 all at once, a good bonding state is achieved at the boundary between the base metal layer 21 and the base metal layer 23. As a result, the plurality of metal layers constituting the conductor pattern 20A are firmly bonded to each other and to the ceramic substrate 10.

In addition, as illustrated in FIG. 10, the base metal layer 21, the base metal layer 23, and the metal layer 22 are each porous metal layers in which the plurality of metal particles 20P are bonded to each other. The density of the plurality of metal particles 22P in the metal layer 22 is higher than the density of the plurality of metal particles 21P in the base metal layer 21. The density of a plurality of metal particles 23P in the base metal layer 23 is higher than the density of the plurality of metal particles 22P in the metal layer 22.

When the dense base metal layer 23 is interposed between the base metal layer 21 and the metal layer 22 as in this modification, the bonding strength between the metal layers is improved as compared with the example described with reference to FIG. 6. In other words, according to this modification, the base metal layer 23 and the metal layer 22 are less likely to peel off from the base metal layer 21 constituting the conductor pattern 20E. As a result, the conductor pattern 20E of the wiring board SUB3 is less likely to peel off from the ceramic substrate 10, so that the reliability can be improved.

Incidentally, the base metal layer 23 contains copper as a main component and has a small weight percentage of silver. For this reason, as a modification, there is an embodiment in which the base metal layer 23 itself is used in place of the metal layer 22 illustrated in FIG. 2 and FIG. 3. In this case, since the base metal layer 23 is denser than the metal layer 22, the electrical characteristics or thermal conduction characteristics are improved as compared with the conductor pattern 20A illustrated in FIG. 2.

However, the dense base metal layer 23 is difficult to thicken as compared with the metal layer 22. Therefore, even if the base metal layer 23 contains copper as a main component and has the small weight percentage of silver as in this modification, it is preferable to form the metal layer 22 so as to cover the base metal layer 23.

In the case of this modification, as illustrated in FIG. 8 and FIG. 9, in the region overlapping with the base metal layer 21, the thickness T22 of the metal layer 22 is larger than the total of the thickness T21 of the base metal layer 21 and a thickness T23 of the base metal layer 23. Therefore, the electrical characteristics or thermal conduction characteristics of the conductor pattern 20A are determined mainly by the characteristics of the metal layer 22.

For example, the thickness T21 of the base metal layer 21 and the thickness T23 of the base metal layer 23 are each about 10 μm to 20 μm. On the other hand, the thickness T22 of the metal layer 22 is about 100 μm to 300 μm.

Since the weight percentage of silver in the base metal layer 23 is small, as a modification relative to FIG. 8 and FIG. 9, the structure in which each of the plurality of side surfaces 21s of the base metal layer 21 is covered with the base metal layer 23 and a part of the base metal layer 23 is in contact with the ceramic substrate 10 is also possible.

However, in order to reliably cover each of the plurality of side surfaces 21s of the base metal layer 21, the thickness T23 of the base metal layer 23 needs to be increased. In this case, as described above, it is necessary to solve the problem that the base metal layer 23 is difficult to thicken.

Therefore, even if the weight percentage of silver in the base metal layer 23 is small, it is preferable that the base metal layer 23 is formed only on the base metal layer 21 and each of the plurality of side surfaces 21s of the base metal layer 21 is covered with the metal layer 22 as in this modification.

The wiring board SUB3 illustrated in FIG. 7 to FIG. 10 is similar to the wiring board SUB1 described with reference to FIG. 1 to FIG. 3, FIG. 5, and FIG. 6 except for the differences described above. Therefore, a duplicated description will be omitted.

### Another Modification of Wiring Board

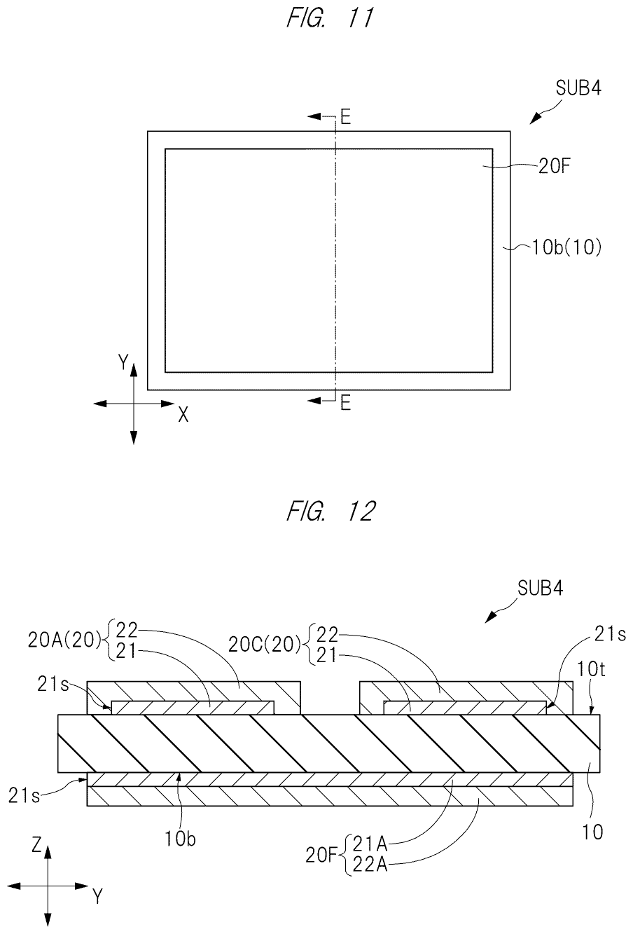

Next, another modification of the wiring board SUB1 will be described. FIG. 11 is a bottom view of a wiring board in a modification relative to the wiring board illustrated in FIG. 1. FIG. 12 is a cross-sectional view taken along the line E-E in FIG. 11.

A wiring board SUB4 illustrated in FIG. 11 and FIG. 12 is different from the wiring board SUB1 illustrated in FIG. 1 to FIG. 3, FIG. 5, and FIG. 6 in that a conductor pattern 20F is also formed on the lower surface 10b in addition to the plurality of conductor patterns 20 formed on the upper surface 10t as illustrated in FIG. 12. In other words, the wiring board SUB4 further includes the conductor pattern 20F formed on the lower surface 10b of the ceramic substrate 10 in addition to the conductor pattern 20A illustrated in FIG. 2.

The case in which a temperature cycle load is applied to the wiring board SUB4 will be studied. When a temperature cycle load is applied to the wiring board SUB4, the linear expansion coefficients are different between the plurality of conductor patterns 20 made up of metal layers and the ceramic substrate 10. For this reason, from the viewpoint of reducing the stress applied to the wiring board SUB4 due to the temperature cycle load, it is preferable to form the conductor patterns having similar linear expansion coefficient on both the upper surface 10t and the lower surface 10b as in the wiring board SUB4.

The conductor pattern 20F formed on the lower surface 10b may not be used as a terminal or wiring. Even in this case, it is preferable that the bond between the conductor pattern 20F and the ceramic substrate 10 is strong. Therefore, the conductor pattern 20F includes a base metal layer 21A and a metal layer 22A stacked on the base metal layer 21A. The base metal layer 21A is the same member as the base metal layer 21 described above except that the plurality of side surfaces 21s are not covered with the metal layer 22A. Moreover, the metal layer 22A is the same member as the metal layer 22 described above except that it does not cover the side surfaces 21s of the base metal layer 21A.

When the conductor pattern 20F is not used as a terminal or wiring, the occurrence of electromigration in the conductor pattern 20F may not cause the degradation in performance of the wiring board SUB4. For this reason, in the example illustrated in FIG. 12, each of the plurality of side surfaces 21s of the base metal layer 21A is not covered with the metal layer 22A. In this case, the manufacturing process of forming the conductor pattern 20F is simpler than the process of forming the plurality of conductor patterns 20 on the upper surface 10t of the ceramic substrate 10.

Though not illustrated, as a modification of the conductor pattern 20F illustrated in FIG. 12, the base metal layer 21A and the metal layer 22A may be formed in the same manner as the conductor pattern 20A. In other words, each of the plurality of side surfaces 21s of the base metal layer 21A of the conductor pattern 20F may be covered with the metal layer 22A. In this case, the occurrence of electromigration due to the silver component contained in the base metal layer 21A can be suppressed, so that the conductor pattern 20F can be used as a terminal or a conduction path such as wiring.

Also, as a modification relative to FIG. 11, a plurality of conductor patterns 20F that are spaced apart from each other may be formed on the lower surface 10b.

### Method of Manufacturing Wiring Board

Next, a method of manufacturing a wiring board will be described. The method of manufacturing the wiring board SUB3 illustrated in FIG. 7 to FIG. 10 will be described as an example. In the case of the method of manufacturing the wiring board SUB1 illustrated in FIG. 1 to FIG. 3, FIG. 5, and FIG. 6, a part of the manufacturing process described below may be omitted. In the following, for the steps that can be omitted in the case of the method of manufacturing the wiring board SUB1, explanations will be given to that effect.

As will be described in detail later, in the method of manufacturing the wiring board described below, for example, when forming each of the plurality of conductor patterns 20 illustrated in FIG. 1, the patterns are formed by applying a paste material containing a plurality of metal particles and firing it. In the case of this method, for example, there are the following advantages as compared with a method of forming conductor patterns by removing a part of a metal film by etching.

In the case of the method of manufacturing the wiring board described below, since there is no need to perform an etching process, undercut due to overetching or residue of the base metal layer due to underetching does not occur. Furthermore, in the case of this embodiment, since there is no need to perform an etching process, many steps including the step of forming an etching mask can be omitted. As a result, manufacturing efficiency is improved.

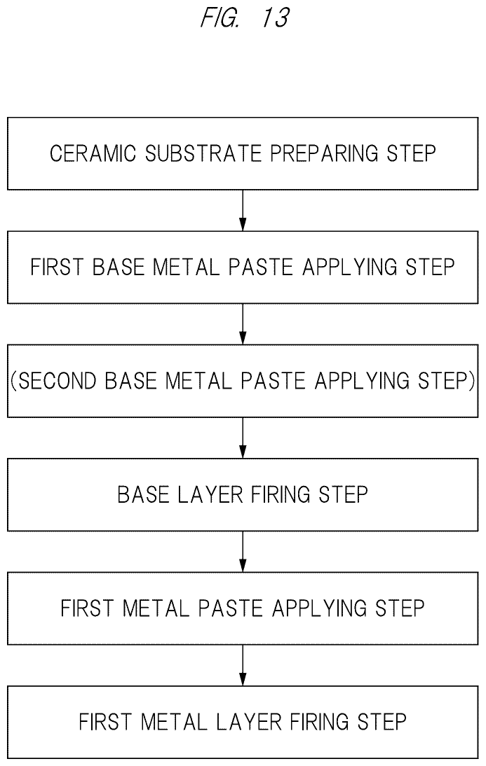

FIG. 13 is an explanatory diagram illustrating an example of a manufacturing process of the wiring board of one embodiment. In FIG. 13, the manufacturing step that can be omitted in the case of the method of manufacturing the wiring board SUB1 illustrated in FIG. 1 to FIG. 3, FIG. 5, and FIG. 6 is illustrated in parentheses.

In the example illustrated in FIG. 13, the method of manufacturing the wiring board includes a ceramic substrate preparing step, a first base metal paste applying step, a second base metal paste applying step, a base layer firing step, a first metal paste applying step, and a first metal layer firing step. Each step will be described in detail below.

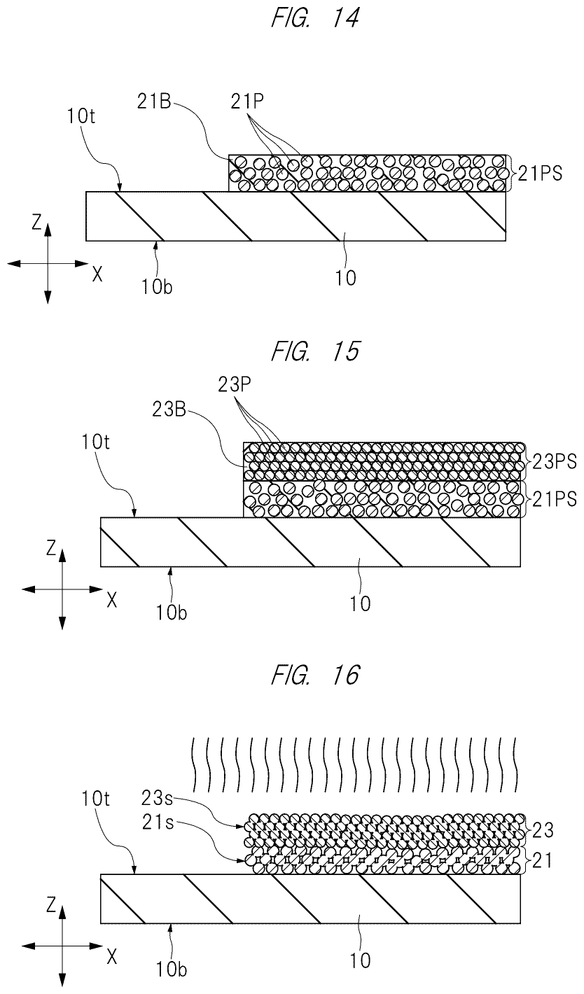

First, in the ceramic substrate preparing step, for example, the ceramic substrate 10 before applying a base metal paste 21PS illustrated in FIG. 14 described later is prepared. The ceramic substrate 10 has the upper surface 10t and the lower surface 10b on an opposite side of the upper surface 10t. The ceramic substrate 10 is made of, for example, silicon nitride or aluminum nitride.

Even when the ceramic substrate 10 is made of, for example, silicon nitride or aluminum nitride, the ceramic substrate 10 contains elements other than silicon and aluminum in some cases. For example, other elements may be added in order to improve the characteristics of the ceramic substrate 10. Alternatively, the ceramic substrate 10 may contain elements inevitably mixed when manufacturing the ceramic substrate 10.

Next, in the first base metal paste applying step, as illustrated in FIG. 14, the base metal paste 21PS is applied onto the upper surface 10t of the ceramic substrate 10. FIG. 14 is an enlarged cross-sectional view illustrating the first base metal paste applying step illustrated in FIG. 13. The base metal paste 21PS is a paste-like material containing the plurality of metal particles 21P and a binder material 21B made of an organic material. The plurality of metal particles 21P are dispersed in the binder material 21B.

The plurality of metal particles 21P contain at least one of titanium particles and chromium particles in addition to copper particles and silver particles. In other words, the base metal paste 21PS contains at least one of titanium particles and chromium particles in addition to copper particles and silver particles.

In this step, for example, the base metal paste 21PS is discharged from a dispenser (not illustrated) onto the upper surface 10t of the ceramic substrate 10, thereby obtaining a state in which the base metal paste 21PS is applied onto the upper surface 10t as illustrated in FIG. 14.

Next, in the second base metal paste applying step, as illustrated in FIG. 15, a base metal paste 23PS is applied onto the base metal paste 21PS. FIG. 15 is an enlarged cross-sectional view illustrating the second base metal paste applying step illustrated in FIG. 13. The base metal paste 23PS is a paste-like material containing the plurality of metal particles 23P and a binder material 23B made of an organic material. The plurality of metal particles 23P are dispersed in the binder material 23B. Note that the binder material 23B is made of, for example, the same organic material as the binder material 21B illustrated in FIG. 14.

The weight percentage of copper particles contained in the base metal paste 23PS is larger than the weight percentage of copper particles contained in the base metal paste 21PS. Also, it is preferable that the weight percentage of silver particles contained in the base metal paste 23PS is smaller than the weight percentage of silver particles contained in the base metal paste 21PS.

The weight percentage of copper particles contained in the base metal paste 21PS is, for example, about 30 to 50% by weight. The weight percentage of silver particles contained in the base metal paste 21PS is, for example, about 20 to 40% by weight. The weight percentage of titanium particles or chromium particles contained in the base metal paste 21PS is, for example, about 1 to 5% by weight. Also, the weight percentage of copper particles contained in the base metal paste 23PS is, for example, 90% by weight or more. Also, the weight percentage of silver particles contained in the base metal paste 23PS is, for example, 5% by weight or less.

In this step, for example, the base metal paste 23PS is discharged from a dispenser (not illustrated) onto the base metal paste 21PS, thereby obtaining a state in which the base metal paste 23PS is applied onto the base metal paste 21PS as illustrated in FIG. 15.

Note that the second base metal paste applying step can be omitted in the case of the method of manufacturing the wiring board SUB1 illustrated in FIG. 1 to FIG. 3, FIG. 5, and FIG. 6. In this case, the base layer firing step is performed after the first base metal paste applying step.

Next, in the base layer firing step, the base metal paste 21PS and the base metal paste 23PS illustrated in FIG. 15 are fired to form a stacked body of the base metal layer 21 and the base metal layer 23 illustrated in FIG. 16. FIG. 16 is an enlarged cross-sectional view illustrating a state in which the base metal layer 21 and the base metal layer 23 are formed by the base layer firing step illustrated in FIG. 13.

In this step, for example, after placing the ceramic substrate 10 on which the base metal paste 21PS and the base metal paste 23PS are applied in a firing furnace (not illustrated), a firing process is performed under preset firing conditions (firing temperature and firing time). In this step, the binder material 21B illustrated in FIG. 14 and the binder material 23B illustrated in FIG. 15 evaporate.

In this step, the plurality of metal particles 21P illustrated in FIG. 14 and the plurality of metal particles 23P illustrated in FIG. 15 are bonded (connected) to each other, so that the base metal layer 21 (see FIG. 16) and the base metal layer 23 (see FIG. 16) which are sintered bodies are obtained. In addition, at the boundary between the base metal layer 21 and the base metal layer 23, the metal particles 21P and the metal particles 23P are partially bonded. In this way, the base layer which is an integrally formed stacked structure is obtained.

If the firing temperature in this step is excessively high, only the paste surface is rapidly fired. As a result, the paste surface and the inside of the paste are fired at an uneven rate, which causes a large difference in the shrinkage rate, so that cracks may occur in the metal layer. In this case, there is a fear that cracks may occur in parts of the base metal layer 21 and the base metal layer 23 illustrated in FIG. 16. Therefore, it is preferable to fire the paste at a firing temperature of 1000° C. or less, for example, about 600 to 900° C.

Incidentally, in the example illustrated in FIG. 13, the base layer firing step is not provided between the first base metal paste applying step and the second base metal paste applying step, and these steps are performed consecutively. Since the thickness of the base metal paste 21PS and the thickness of the base metal paste 23PS illustrated in FIG. 15 are as small as about 10 to 20 μm, respectively, the organic components contained in the paste materials can be removed all at once if the base layer firing step is performed after staking the two layers.

Also, the manufacturing process in which the base layer firing step is performed after the first base metal paste applying step and the second base metal paste applying step are performed consecutively as illustrated in FIG. 13 is preferable in the following points.

As described above, the base metal paste 21PS illustrated in FIG. 14 contains many silver particles in addition to copper particles. Further, the base metal paste 21PS contains titanium particles or chromium particles. The study by the inventors of this application has revealed that a metal thin film made of silver, titanium, or chromium may be formed on the surface of the obtained base metal layer 21 (see FIG. 16) when the base metal paste 21PS is fired alone. When a metal thin film containing many metals other than copper is formed on the surface of the base metal layer 21 in this way, it is difficult to bond the base metal layer 21 and the base metal layer 23 illustrated in FIG. 16 in some cases.

On the other hand, when the base metal paste 21PS and the base metal paste 23PS illustrated in FIG. 15 are fired all at once as in this embodiment, they are sintered without forming a thin metal film on the surface of the base metal layer 21, so that the good bonding state is achieved between the base metal layer 21 and the base metal layer 23 illustrated in FIG. 16.

Furthermore, since the base metal layer 23 is a metal layer containing copper as a main component as described above, a metal film made of metal other than copper such as silver, titanium, or chromium is less likely to be formed on the surface of the base metal layer 23. Therefore, the bonding state between the base metal layer 23 and the metal layer 22 illustrated in FIG. 18 described later is also good in the first metal layer firing step illustrated in FIG. 13.

When the manufacturing process includes the second base metal paste applying step illustrated in FIG. 13, the number of steps increases as compared with the case in which this step is omitted, but from the viewpoint of improving the reliability of the conductor pattern, it is preferable that the manufacturing process includes the second base metal paste applying step.

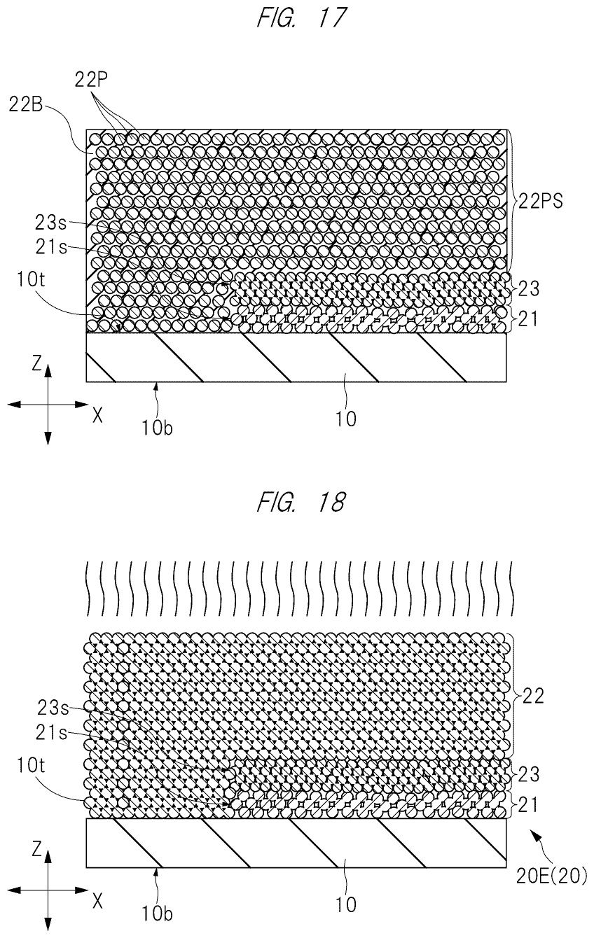

Next, in the first metal paste applying step, as illustrated in FIG. 17, the metal paste 22PS is applied so as to entirely cover the base metal layer 21 and the base metal layer 23. FIG. 17 is an enlarged cross-sectional view illustrating the first metal paste applying step illustrated in FIG. 13.

The metal paste 22PS is a paste-like material containing the plurality of metal particles 22P and a binder material 22B made of an organic material. The plurality of metal particles 22P are dispersed in the binder material 22B. Note that the binder material 22B is made of, for example, the same organic material as the binder material 21B illustrated in FIG. 14.

The weight percentage of the copper particles contained in the metal paste 22PS is larger than the weight percentage of the copper particles contained in the base metal paste 21PS. Also, the weight percentage of the silver particles contained in the base metal paste 21PS is smaller than the weight percentage of the silver particles contained in the base metal layer.

In this step, for example, the metal paste 22PS is discharged from a dispenser (not illustrated) onto the base metal layer 23, thereby obtaining a state in which the metal paste 22PS is applied onto the base metal layer 23 as illustrated in FIG. 17. Note that the metal paste 22PS is applied onto the base metal layer 21 in the case of the method of manufacturing the wiring board SUB1 illustrated in FIG. 1 to FIG. 3, FIG. 5, and FIG. 6.

As illustrated in FIG. 17, in the case of this embodiment, the side surfaces 21s of the base metal layer 21 are covered with the metal paste 22PS in the first metal paste applying step. Similarly, the side surfaces 23s of the base metal layer 23 are covered with the metal paste 22PS. Although one side surface 21s of the base metal layer 21 and one side surface 23s of the base metal layer 23 are illustrated in FIG. 17, all of the side surfaces 21s of the base metal layer 21 and all of the side surfaces 23s of the base metal layer 23 are covered with the metal paste 22PS in this step. Also, the metal paste 22PS is applied such that a part of the metal paste 22PS is in contact with the upper surface 10t of the ceramic substrate 10. As a result, the base metal layer 21 and the base metal layer 23 are sealed with the metal paste 22PS.

In this step, since all of the side surfaces 21s of the base metal layer 21 and all of the side surfaces 23s of the base metal layer 23 are covered with the metal paste 22PS, the occurrence of electromigration due to the base metal layer 21 can be suppressed as described above.

Next, in the first metal layer firing step, the metal paste 22PS illustrated in FIG. 17 is fired to form the metal layer 22 illustrated in FIG. 18. FIG. 18 is an enlarged cross-sectional view illustrating a state in which the metal layer is formed by the first metal layer firing step illustrated in FIG. 13.

In this step, for example, after placing the ceramic substrate 10 on which the metal paste 22PS is applied in a firing furnace (not illustrated), a firing process is performed under preset firing conditions (firing temperature and firing time). In this step, the binder material 22B illustrated in FIG. 17 evaporates.

In this step, the plurality of metal particles 22P illustrated in FIG. 17 are bonded (connected) to each other, so that the metal layer 22 (see FIG. 18) which is a sintered body is obtained. In addition, at the boundary between the metal layer 22 and the base metal layer 23, the metal particles 22P are partially bonded to the base metal layer 23. In this way, the conductor pattern 20E which is an integrally formed stacked structure (see FIG. 18) is obtained.

As described above, if the firing temperature in the firing step is excessively high, there is a fear that cracks may occur during the firing, causing deformation in the applied paste. Therefore, in this step as well, it is preferable to fire the paste at a firing temperature of 1000° C. or less, for example, about 600 to 900° C. as in the base layer firing step described above.

As illustrated in FIG. 13, in the case of this embodiment, the base layer firing step is performed before the first metal paste applying step. In other words, the base layer and the metal layer 22 are not formed at the same time. The metal layer 22 is the main layer of the conductor pattern 20, and thus needs to have a certain thickness. Therefore, when the base metal paste 21PS and the base metal paste 23PS illustrated in FIG. 15 are sealed with the metal paste 22PS illustrated in FIG. 17 and then fired all at once, the binder material 21B (see FIG. 14) and the binder material 23B (see FIG. 15) cannot be sufficiently removed in some cases.

In the case of this embodiment, since the base layer firing step is performed before the first metal paste applying step, the binder material 21B (see FIG. 14) and the binder material 23B (see FIG. 15) can be reliably removed.

By the above steps, the wiring board SUB3 described with reference to FIG. 7 to FIG. 10 or the wiring board SUB1 illustrated in FIG. 1 to FIG. 3, FIG. 5, and FIG. 6 can be obtained. When the plurality of conductor patterns 20 each have the same structure, the plurality of conductor patterns 20 can be formed all at once. Therefore, it is possible to avoid the decrease in manufacturing efficiency due to a large number of conductor patterns 20.

### Modification of Manufacturing Method

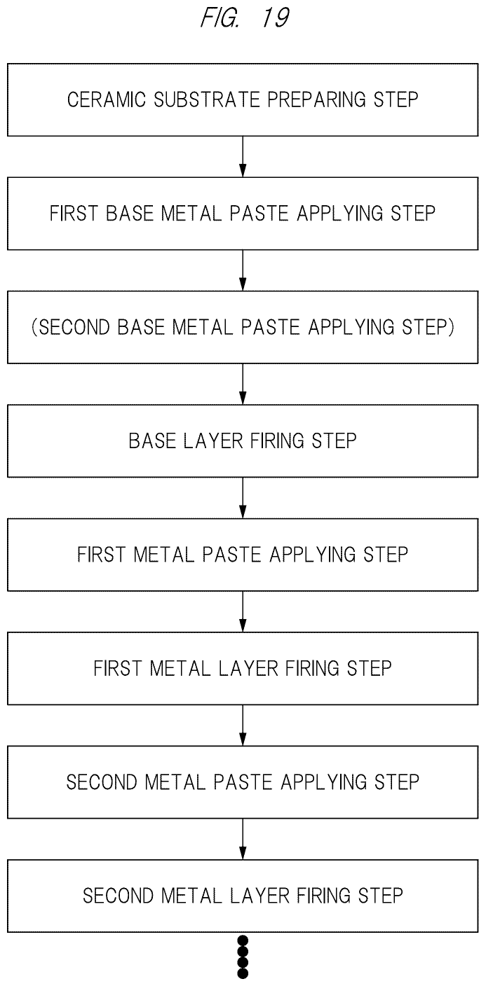

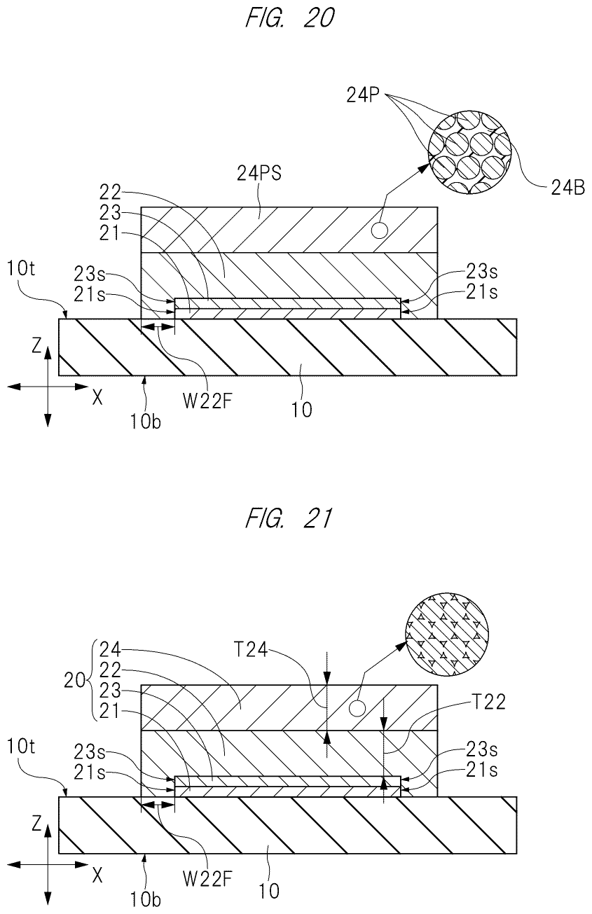

Next, a modification of the method of manufacturing the wiring board will be described. FIG. 19 is an explanatory diagram illustrating an example of a manufacturing process of a wiring board in the modification relative to FIG. 13. FIG. 20 is an enlarged cross-sectional view illustrating the second metal paste applying step illustrated in FIG. 19. FIG. 21 is an enlarged view illustrating the second metal layer firing step illustrated in FIG. 19.

The modification illustrated in FIG. 19 is different from the method of manufacturing the wiring board illustrated in FIG. 13 in that it includes a second metal paste applying step and a second metal layer firing step after the first metal layer firing step.

As described above, if the thickness of the paste to be fired at a time becomes large, the binder material contained in the base metal paste 21PS and the base metal paste 23PS is not sufficiently removed in some cases. According to the study by the inventors of this application, from the viewpoint of removing the binder material, the thickness T22 of the metal layer 22 illustrated in FIG. 2 and FIG. 8 is preferably 300 μm or less.

On the other hand, the thickness of the conductor pattern 20 (see FIG. 2) is not limited to 300 μm or less, and may be required to be, for example, about 1 mm. In the case of this modification, the conductor pattern 20 with a thickness of more than 300 ρm can be obtained by repeating the first metal paste applying step and the first metal layer firing step described above.

In the second metal paste applying step illustrated in FIG. 19, a metal paste 24PS is applied onto the metal layer 22 as illustrated in FIG. 20. The metal paste 24PS contains a plurality of metal particles 24P and a binder material 24B. The metal paste 24PS is the same material as the metal paste 22PS illustrated in FIG. 17. For example, the plurality of metal particles 24P contain copper particles at the same weight percentage as that of the plurality of metal particles 22P illustrated in FIG. 17. Further, the binder material 24B is made of the same organic material as the binder material 22B illustrated in FIG. 17.

When the metal paste 22PS illustrated in FIG. 17 and the metal paste 24PS illustrated in FIG. 20 are made of the same material, it is possible to bond the metal layer 22 and the metal layer 24 illustrated in FIG. 21 well at the boundary therebetween.

Next, in the second metal layer firing step illustrated in FIG. 19, after the second metal paste applying step, the metal paste 24PS illustrated in FIG. 20 is fired to form the metal layer 24 illustrated in FIG. 21. In this step, the plurality of metal particles 24P illustrated in FIG. 20 are bonded (connected) to each other, so that the metal layer 24 (see FIG. 21) which is a sintered body is obtained.

In addition, at the boundary between the metal layer 24 and the metal layer 22, the metal particles 24P are partially bonded to the metal layer 22. When the metal paste 24PS illustrated in FIG. 21 is the same material as the metal paste 22PS illustrated in FIG. 17, the boundary between the metal layer 22 and the metal layer 24 is bonded to such an extent that it is difficult to visually recognize it.

Also, it is preferable that the firing temperature in this step is 1000° C. or less, for example, about 600 to 900° C. as in the base layer firing step and the first metal layer firing step described above.

A thickness T24 (see FIG. 21) of the metal layer 24 obtained in this step is 300 μm or less. When the thickness T22 and the thickness T24 illustrated in FIG. 21 are each 300 μm, the conductor pattern 20 having a thickness of 600 μm in total can be obtained.

FIG. 19 illustrates the process up to the second metal layer firing step, but if the thickness of the conductor pattern 20 is to be further increased, the second metal paste applying step and the second metal layer firing step are repeated after the second metal layer firing step. In this way, the conductor pattern 20 having a thickness of more than 600 μm can be obtained.

The metal layer 22 (see FIG. 21) and the metal layer 24 (see FIG. 21) are layers whose thicknesses are larger than those of the base metal layers (base metal layer 21 and base metal layer 23 illustrated in FIG. 21). Therefore, if the metal paste 22PS (see FIG. 17) and the metal paste 24PS (see FIG. 20) are fired all at once just as the base metal layer 21 and the base metal layer 23 are formed all at once in the manufacturing step of the base metal layer, there is a fear that the shape of the wiring will be distorted before firing due to the weights of the stacked metal pastes themselves. For this reason, by applying the metal paste 24PS after the metal layer 22 is formed by firing the metal paste 22PS, a thick wiring layer can be formed without distorting the shape.

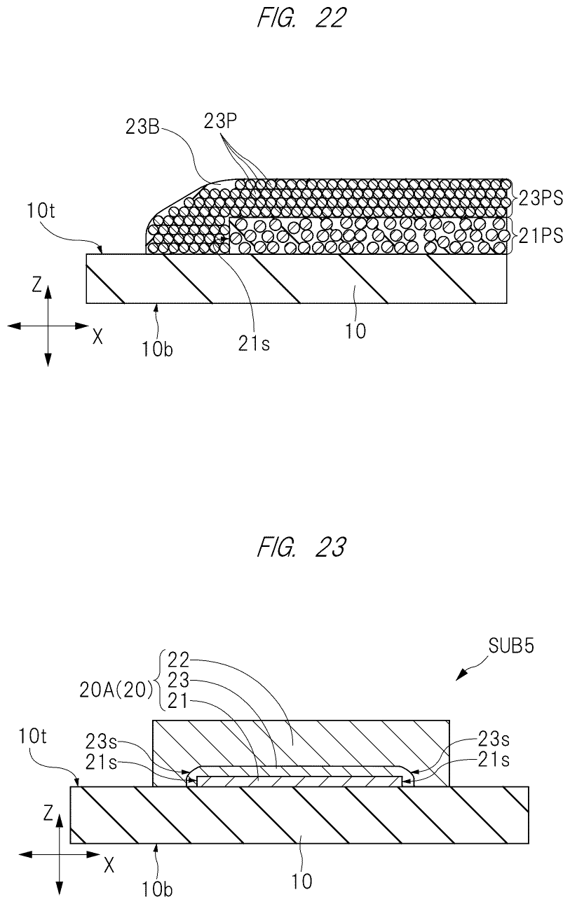

FIG. 22 is an enlarged cross-sectional view illustrating the second base metal paste applying step in a modification relative to FIG. 15. FIG. 23 is an enlarged cross-sectional view of a conductor pattern obtained in the modification illustrated in FIG. 22.

The modification illustrated in FIG. 22 is different from the method of manufacturing the wiring board illustrated in FIG. 15 in that the side surfaces 21s of the base metal paste 21PS are covered with the base metal paste 23PS in the second base metal paste applying step.

Furthermore, as illustrated in FIG. 23, a wiring board SUB5 manufactured by the method of manufacturing the wiring board illustrated in FIG. 22 is different from the wiring board SUB3 illustrated in FIG. 8 in the following points. That is, in the conductor pattern 20A of the wiring board SUB5, the side surfaces 21s of the base metal layer 21 are covered with the base metal layer 23, and the side surfaces 23s of the base metal layer 23 are covered with the metal layer 22.

As described above, when the base metal paste 21PS and the base metal paste 23PS illustrated in FIG. 22 are fired all at once in the manufacturing process of the wiring board, they are sintered before a metal film is formed on the surface of the base metal paste 21PS, so that a good bonding state is achieved between the base metal layer 21 and the base metal layer 23 illustrated in FIG. 23.

Therefore, in the case of this modification, the bonding strength between the side surfaces 21s of the base metal layer 21 and the base metal layer 23 is better than the bonding strength between the side surfaces 21s of the base metal layer 21 and the metal layer 22 illustrated in FIG. 8.

In the foregoing, several representative embodiments have been described with reference to the drawings, but there are still various modifications of the above-mentioned embodiments and modifications. As long as there is no contradiction to the above description, parts of the embodiments can be changed as appropriate. Also, for example, parts of the above-mentioned embodiments and modifications can be applied in combination with parts of other embodiments.

What is claimed is:

1. A wiring board comprising:
a ceramic substrate having a first surface and a second surface on an opposite side of the first surface; and
a first conductor pattern formed on the first surface of the ceramic substrate,
wherein the first conductor pattern includes:
a first base metal layer formed on the first surface of the ceramic substrate; and
a first metal layer formed on the first surface of the ceramic substrate so as to entirely cover the first base metal layer,
wherein the first base metal layer contains at least one of titanium and chromium in addition to copper and silver,
wherein the first metal layer contains copper as a main component and a weight percentage of silver contained in the first metal layer is smaller than a weight percentage of the silver contained in the first base metal layer, and
wherein side surfaces of the first base metal layer are covered with the first metal layer.

2. The wiring board according to claim 1,
wherein each of the first base metal layer and the first metal layer is a porous metal layer in which a plurality of metal particles are bonded to each other, and
wherein a density of the plurality of metal particles in the first metal layer is higher than a density of the plurality of metal particles in the first based metal layer.

3. The wiring board according to claim 2,
wherein, in a region in which the first metal layer and the first base metal layer are overlapped with each other, a thickness of the first metal layer is larger than a thickness of the first base metal layer.

4. The wiring board according to claim 1,
wherein the first conductor pattern further includes a second base metal layer formed on the first base metal layer, and
wherein each of the first base metal layer and the second base metal layer is entirely covered with the first metal layer, including the side surfaces of the first base metal layer and side surfaces of the second base metal layer.

5. The wiring board according to claim 4,
wherein the second base metal layer contains copper as a main component,
wherein each of the first base metal layer, the second base metal layer, and the first metal layer is a porous metal layer in which a plurality of metal particles are bonded to each other,
wherein a density of the plurality of metal particles in the first metal layer is higher than a density of the plurality of metal particles in the first based metal layer, and
wherein a density of the plurality of metal particles in the second base metal layer is higher than the density of the plurality of metal particles in the first metal layer.

6. The wiring board according to claim 4,
wherein, in a region in which the first metal layer, the first base metal layer, and the second base metal layer are overlapped with each other, a thickness of the first metal layer is larger than a total of a thickness of the first base metal layer and a thickness of the second base metal layer.

7. The wiring board according to claim 1,
wherein the first conductor pattern further includes a second base metal layer formed on the first base metal layer, and
wherein side surfaces of the first base metal layer are covered with the second base metal layer and side surfaces of the second base metal layer are covered with the first metal layer.

8. The wiring board according to claim 1,
wherein an area of a contact surface between the first base metal layer and the ceramic substrate is larger than an area of a contact surface between the first metal layer and the ceramic substrate.

9. The wiring board according to claim 1, further comprising a second conductor pattern formed on the first surface of the ceramic substrate so as to be spaced apart from the first conductor pattern,
wherein the first conductor pattern and the second conductor pattern are arranged adjacent to each other in plan view, and
wherein the second conductor pattern includes:
the first base metal layer; and
the first metal layer.

10. The wiring board according to claim 1,
wherein the ceramic substrate is made of silicon nitride or aluminum nitride.

11. The wiring board according to claim 1, further comprising a third conductor pattern formed on the second surface of the ceramic substrate.

12. A method of manufacturing a wiring board comprising:
(a) preparing a ceramic substrate having a first surface and a second surface on an opposite side of the first surface;
(b) applying a first base metal paste onto the first surface of the ceramic substrate;
(c) forming a first base metal layer by firing the first base metal paste;
(d) after the (c), applying a first metal paste so as to entirely cover the first base metal layer; and
(e) after the (d), forming a first metal layer by firing the first metal paste,
wherein the first base metal paste contains at least one of titanium particles and chromium particles in addition to copper particles and silver particles,
wherein a weight percentage of copper particles contained in the first metal paste is larger than a weight percentage of the copper particles contained in the first base metal paste, and a weight percentage of silver particles contained in the first metal paste is smaller than a weight percentage of the silver particles contained in the first base metal paste, and
wherein, in the (d), side surfaces of the first base metal layer are covered with the first metal paste.

13. The method of manufacturing the wiring board according to claim 12, further comprising (f) after the (b) and before the (c), applying a second base metal paste on the first base metal paste,
wherein, in the (c), the first base metal layer and a second base metal layer stacked on the first base metal layer are formed all at once by firing the first base metal paste and the second base metal paste all at once, and
wherein a weight percentage of copper particles contained in the second base metal paste is larger than the weight percentage of the copper particles contained in the first metal paste.

14. The method of manufacturing the wiring board according to claim 13, further comprising:
(g) after the (e), applying a second metal paste onto the first metal layer; and
(h) after the (g), forming a second metal layer by firing the second metal paste.

15. The method of manufacturing the wiring board according to claim 14,
wherein the second metal paste is a same material as the first metal paste.

16. The method of manufacturing the wiring board according to claim 13,
wherein, in the (f), side surfaces of the first base metal paste are covered with the second base metal paste.
